(19) United States
(12) Patent Application Publication
(10) Pub. No.: US 2026/0291168 A1
(43) Pub. Date: Sep. 24, 2026

(54) BROAD-AREA SEMICONDUCTOR LASER WITH IMPROVED BEAM QUALITY19149945

(71) Applicant: Ferdinand-Braun-Institut gGmbH Leibniz-Institut für Höchstfrequenztechnik, Berlin (DE)

(72) Inventors: Mohammad Jarez Miah, Berlin (DE); Paul Crump, Berlin (DE); Christian Dominik Martin, Berlin (DE)

(21) Appl. No.: 19/151,289

(22) PCT Filed: Dec. 12, 2023
(86) PCT No.: PCT/EP2023/085269

§ 371 Date: Jul. 25, 2025

(30) Foreign Application Priority Data
Jan. 27, 2023 (DE) 10 2023 102 047.1

(51) Int. Cl. H01S 5/024; H01S 5/042; H01S 5/40

(52) U.S. Cl. CPC H01S 5/02461; H01S 5/0421; H01S 5/4025

(57) ABSTRACT

The present invention relates to a semiconductor laser having improved beam quality and in particular a semiconductor-based high-performance laser bar having reduced thermal lensing and reduced lateral far-field divergence by means of an inhomogeneous sub-contact structure in a contact region.

A claimed contact region of a single broad-area laser emitter comprises a semiconductor contact layer (12) of an epitaxial layer of the broad-area laser emitter, a metal contact layer (10) for making planar surface contact with the semiconductor contact layer (12), wherein a structured region (14) comprising individual sub-contacts (16) is formed under the metal contact layer (10) in the semiconductor contact layer (12) for spatially splitting an operating current which can be supplied over the metal contact layer (10), wherein the width w_{sub} and/or spacing a_{sub} of the individual sub-contacts (16) of the structured region (14) varies in a lateral direction of the broad-area laser emitter.

### DESCRIPTION

The present invention relates to a semiconductor laser having improved beam quality and in particular a semiconductor-based high-performance laser bar having reduced thermal lensing and reduced lateral far-field divergence by means of an inhomogeneous sub-contact structure in a contact region.

### PRIOR ART

High-performance semiconductor lasers having low beam divergence are of vital importance in many applications. For instance, kW-class semiconductor laser bars contain a plurality of broad area lasers (BAL) arranged in parallel with one another, which typically have a lateral stripe width W of between 50 μm and 1200 μm. Corresponding laser bars having a power of approx. 2 kW in quasi-continuous operation or 1 kW in continuous operation have already been successfully produced (M. J. Miah et al., “Optimizing vertical and lateral waveguides of kW-class laser bars for higher peak power, efficiency and lateral beam quality,” IEEE Photon. J. 14 (3), page 1525505, 2022; P. Crump et al., “Increased conversion efficiency at 800 W continuous wave output from single 1-cm diode laser bars at 940 nm,” CLEO/Europe-EQEC, 2021).

The heat/temperature profile within the individual emitters and in the entire laser bar is, however, a major obstacle to reaching yet higher powers and for the beam quality (i.e. for the beam parameter product (BPP)). Experimental studies (M. Winterfeldt et al., “High beam quality in broad area lasers via suppression of lateral carrier accumulation,” IEEE Photon. Technol. Lett. 27 (17), p. 1809, 2015; P. Crump et al., “Experimental studies into the beam parameter product of GaAs high-power diode lasers,” IEEE J. Sei. Top. Quant. Electron 28 (1), page 1501111, 2021) demonstrate that, during laser operation, significant thermal lensing forms and the resulting lensing effect becomes increasingly evident at a higher operating power.

In this regard, the simulated temperature distributions are shown in FIG. 1 within a 1 cm wide kW-class GaAs laser bar, for example, which comprises 8 BAL emitters having a lateral stripe width W of ≈1100 μm at different power losses. In order to avoid stimulating undesired lateral modes, the individual emitters of the laser bar have homogeneously sub-structured GaAs contact layers, with these structures comprising individual sub-contacts each having a width of 20 μm and a spacing of 9 μm (corresponding to a period of 29 μm) in the semiconductor contact layer in the simulation shown by way of example. The central 6 emitters (emitters 2 to 7) of the laser bar exhibit symmetrical and largely identical temperature distributions, while, at the outer edge emitters (emitters 1 and 8), asymmetrical temperature distributions are exhibited having a significantly reduced temperature toward the edges of the emitter. At an operating power of 1 KW (corresponding to a power loss of approximately 603 W), the temperature deviation ΔT between the center of the central emitters and their edges is 4.4 K. For the edge emitters (emitters 1 and 8), the deviation between the relevant center and the edges increases even to above 10 K. The resulting thermal lensing that is generated in the simulated laser bar within each individual emitter gives rise to more higher-order modes and therefore worsens the beam quality of the emitters.

In the prior art, different approaches are known to mitigate the thermal lensing effect in the individual emitters and in the laser bar in order to improve the BPP. This can, for example, be carried out by accordingly adapting the epitaxial design (P. Crump et al., “Increased conversion efficiency at 800 W continuous wave output from single 1-cm diode laser bars at 940 nm,” CLEO/Europe-EQEC, 2021) or by forming a structured metal contact (A. Bachmann et al., “Recent brightness improvement of 976 nm high power laser bars,” Proc. SPIE 10086, page 1008602, 2017).

Other approaches for improving the BPP of high-performance lasers or laser bars by leveling off the temperature profile within the laser module are based, for example, on modifying the design of the epitaxial layer (DE 10 2020 133 368 A1) and the lateral bar layout, the use of pedestals (J. G. Bai et al., Proc SPIE 7953, 79531F-1, 2011) or additional heat input (J. P. Hohimer et al., “Mode control in broad-area diode lasers by thermally induced lateral index tailoring,” Appl. Phys. Lett. 52 (4), 260-262, 1988). Although the measures known from the prior art alone can significantly reduce the thermal lensing effect, it needs to be suppressed further in order to provide yet higher powers and to further improve the beam quality.

### DISCLOSURE OF THE INVENTION

An object of the present invention is therefore to provide a semiconductor laser having reduced thermal lensing and reduced lateral far-field divergence in which, in order to improve the BPP, the thermal lensing effect is reduced in the individual emitters or in the laser bar by varying the temperature profile in the lateral direction on the basis of an existing epitaxial structure, i.e. without complex adjustments to the basic epitaxial design or in the layer structure.

These objects are achieved according to the invention by the features of independent claims 1, 11 and 12. Expedient configurations of the invention are contained in the respective dependent claims. In particular, in this regard, a homogeneous sub-structure distribution already known from the prior art is adapted in the contact region of broad-area laser emitters in laser bars (M. J. Miah et al., “Optimizing vertical and lateral waveguides of kW-class laser bars for higher peak power, efficiency and lateral beam quality,” IEEE Photon. J. 14 (3), page 1525505, 2022) and is fundamentally developed further to achieve the stated object.

A claimed contact region of a broad-area laser emitter comprises a semiconductor contact layer of an epitaxial layer of the broad-area laser emitter, a metal contact layer for making planar surface contact with the semiconductor contact layer, wherein a structured region comprising individual sub-contacts is formed under the metal contact layer in the semiconductor contact layer for spatially splitting an operating current which can be supplied over the metal contact layer, wherein the width W_{sub} and/or spacing a_{sub} Of the individual sub-contacts varies in a lateral direction of the broad-area laser emitter (i.e. within a single laser diode along the slow axis). Furthermore, a broad-area laser emitter having a contact region according to the invention is provided.

Broad-area laser emitters are well known in the prior art, and in this regard reference is made to the relevant technical literature. Semiconductor laser structures of this kind comprise an epitaxial layer made up of differently doped semiconductor materials, with recombination of corresponding charge carriers taking place at the boundary between an n-doped and p-doped region for beam generation. The charge carriers are usually introduced into the epitaxial structure via a metal contact layer (along the vertical axis of the semiconductor laser). To adapt to the metal contact layer, the epitaxial layer comprises a semiconductor contact layer as the adaptation layer at the boundary with the metal contact layer. By means of this layer, the metal semiconductor junction can be produced with the lowest possible contact resistance.

It is also known from the prior art to form a sub-structure formed under the metal contact layer in the semiconductor contact layer (M. J. Miah et al., “Optimizing vertical and lateral waveguides of kW-class laser bars for higher peak power, efficiency and lateral beam quality,” IEEE Photon. J. 14 (3), page 1525505, 2022). This in particular serves to prevent stimulation of undesired lateral modes in the broad-area laser emitter. In the prior art, however, the sub-structures are designed such that the width W_{sub} and the spacing a_{sub} Of the individual sub-contacts in the semiconductor contact layer under the metal contact layer are constant in a lateral direction. The sub-structure distribution is thus homogeneous. By contrast, in the present invention, an inhomogeneous sub-structure distribution is produced, such that the width w_{sub} and/or the spacing a_{sub} of the individual sub-contacts in the semiconductor contact layer under the metal contact layer of the laser emitter vary in a lateral direction.

The structured region having the individual sub-contacts can be limited to the semiconductor contact layer and extend in part or completely therethrough (in the tangential direction of the broad-area laser emitter). Furthermore, the structured region can also extend into one or more underlying epitaxial layers. Owing to the structuring, conductive regions having low electrical resistance (sub-contacts) and regions having high electrical resistance (blocking-state regions between adjacent sub-contacts in the structured region of a single broad-area semiconductor laser) are alternately formed.

In the regions that are supplied with current via the individual sub-contacts (i.e. by the individual current-conducting regions formed in the structured semiconductor contact layer), more heat is generated. If the distribution of the regions pumped in a structured manner by the flow of current is modified within the laser stripe, the heat distribution resulting in the emitter is thus also modified, and this can be used according to the invention for the positive effect of leveling off the thermal lensing. In the invention set out, the heat distribution is thus redistributed by the modification to the size and the mutual arrangement of the individual sub-contacts of a sub-structure known per se having a homogeneous sub-structure distribution within the semiconductor contact layer.

If, for example, the width of the individual sub-contacts at the edges of the laser stripe is increased, this allows for a higher total current owing to the electrical resistance that progressively becomes lower, and this in turn results in a higher local total power loss of the sub-contact. Wider sub-contacts thus have a higher heat load overall and increase the proportion of the heat toward the stripe edges of the laser stripe. This in turn minimizes the drop in temperature at the edges of the emitter and ultimately results in a temperature profile that is flatter overall.

If the mutual spacing of the individual sub-contacts additionally decreases, the pumped regions have greater thermal interaction with one another, which prevents a significant drop in temperature in the unpumped region between the pumped regions and thus likewise brings about a flatter temperature distribution.

The concept of the present invention is thus based on the fact that an inhomogeneously structured contact region is used to level off the temperature profile within a single semiconductor laser emitter (also referred to as a laser stripe, laser diode, broad-area emitter or the like) and thus to reduce the lateral beam divergence. By contrast with homogeneous, periodically structured contact regions in the prior art, which accordingly extend over the entire width of each individual laser stripe in a conventional laser bar (see FIG. 1), wider sub-contacts toward the edges of the emitters are preferably used. This approach can be used to improve the performance and the beam quality both of individual emitters having a large aperture and of laser bars constructed from a plurality of such individual emitters when the sub-structure distribution is accordingly tailored to their thermal profiles.

The contact region of the broad-area laser emitter preferably extends over a lateral stripe width W≥150 μm, more preferably W≥200 μm. In this case, this is the lateral stripe width W of a single broad-area laser emitter. The broad-area laser emitter preferably has a length of L≥2 mm in the longitudinal direction. The width of a sub-contact is preferably W_{sub}≤200 μm, preferably W_{sub}<50 μm.

The spacing between adjacent sub-contacts is preferably a_{sub}≤50 μm, more preferably a_{sub}<20 μm, yet more preferably a_{sub}<10 μm. The spacing between adjacent sub-contacts of the sub-structure is preferably a_{sub}>1 μm. Minimum spacings of this kind allow the structures to be provided in a simplified manner, for example by means of photoresist. A higher fill factor F can be achieved in the sub-structure by small spacings between adjacent sub-contacts. As a result, losses (e.g. owing to increased electrical series resistances) can be prevented.

The period of the sub-contacts p_{sub} is above W_{sub} and a_{sub} is defined by p_{sub}=W_{sub}+a_{sub}. Preferably, p_{sub} varies by less than 20%, more preferably by less than 10%, in a single broad-area laser emitter, and more preferably p_{sub} is identical for all the sub-contacts and spacings a_{sub}.

A fill factor F of the sub-structure is preferably between 30% and 95%, more preferably between 60% and 95%. In this case, the fill factor F is defined as the ratio between the pumped area (i.e. the total width of all the n sub-contacts, n×W_{sub}) within the individual emitter and the total width of the individual emitter W (width of all the sub-contacts and their spacings), F=(n×W_{sub})/W.

Preferably, the width of the sub-contacts W_{sub} in the semiconductor contact layer under the metal contact layer increases toward the edges of the structured region and/or the spacing of the sub-contacts a_{sub} in the semiconductor contact layer under the metal contact layer decreases toward the edges of the structured region, wherein the variation in the width w_{sub} and/or the spacing a_{sub} of the center of the structured region toward its edges is preferably at least 10%. In this case, “variation in the width” is understood to mean the relative difference between the width of the sub-contacts in the center of the emitter and the width of the sub-contacts at the edge of the emitter. In a similar manner, “variation in the spacing” of the sub-contacts is understood to mean the relative difference between the spacing of the sub-contacts in the center of the emitter and the spacing of the sub-contacts at the edge of the emitter.

Preferably, the width w_{sub} and/or spacing a_{sub} of the sub-contacts in the semiconductor contact layer under the metal contact layer additionally varies in a longitudinal direction from a front face of the broad-area laser emitter toward a rear face of the broad-area laser emitter. Preferably, in this case, the width of the sub-contacts w_{sub} increases in the longitudinal direction and/or the spacing of the sub-contacts a_{sub} decreases in the longitudinal direction, wherein the variation in the width w_{sub} and/or the spacing a_{sub} from the front face of the broad-area laser emitter to the rear face of the broad-area laser emitter is preferably at least 10%. This kind of variation in the sub-structure along the resonator axis can predominantly be used to equalize temperature fluctuations in the longitudinal direction. In particular, for reducing the flow of current and for decreasing the local temperature, the individual sub-contacts under the metal contact layer on the front face of the broad-area laser emitter can be formed to be at least 10% narrower than on the rear face of the broad-area laser emitter.

The contact region according to the invention is preferably produced by structuring the resistance of the semiconductor contact layer by means of implantation or doping of foreign atoms, or by implementation of p-n junctions, for example by two-step epitaxy or by incorporating layers having a wide bandgap. An increase in the electrical resistance by 100 times is thus preferably implemented in the implanted or doped regions. The sub-structures can be generated by using implantation and/or epitaxial overgrowth techniques having a typical residual layer thickness of 2 μm>dᵣₑₛ>0 μm. In this case, the residual layer thickness is referred to as the spacing between one face of the active layer (e.g. its upper face) and the face of the implanted/doped region facing the active layer (e.g. its lower face). A metal contact layer can preferably be an electroplated gold layer (Au) on at least one metal-alloy layer stack (e.g. Ti/Pt/Au).

Another aspect of the present invention relates to a laser bar comprising a plurality of broad-area laser emitters arranged beside one another, wherein at least one broad-area laser emitter is formed having a contact region according to the invention. All the broad-area laser emitters of the laser bar are preferably formed to comprise a contact region according to the invention. In an exemplary laser bar having a typical bar width of W_{LB}=1 cm, between approximately 5 and 80 individual emitters can preferably be arranged in this case, depending on the specific design.

At least one broad-area laser emitter having a contact region according to the invention is preferably arranged in the central region of the laser bar and the individual sub-contacts of the broad-area laser emitter are formed to be symmetrical relative to the center of the structured region in the lateral direction. All the broad-area laser emitters arranged in the central region of the laser bar preferably have a contact region according to the invention, wherein the individual sub-contacts of these broad-area laser emitters are formed to be symmetrical relative to the center of the structured region in the lateral direction.

At least one broad-area laser emitter having a contact region according to the invention is preferably arranged in the edge region of the laser bar and the individual sub-contacts of the broad-area laser emitter are formed to be asymmetrical relative to the center of the structured region in the lateral direction. All the broad-area laser emitters arranged in the edge region of the laser bar preferably have a contact region according to the invention, wherein the individual sub-contacts of these broad-area laser emitters are formed to be asymmetrical relative to the center of the structured region in the lateral direction.

The variation in the width w_{sub} and/or the spacing a_{sub} of the sub-contacts from the center of the structured region toward the central region of the laser bar is preferably less than toward the edges of the laser bar, wherein the difference in the variation is preferably at least 10%.

Since, for example in the 1 cm diode laser bar having 8 emitters that is shown by way of example in FIG. 1, the central emitters (emitters 2-7) have a symmetrical temperature progression, the sub-contacts of the single broad-area laser emitters should preferably be arranged symmetrically with a contact region according to the invention on their two sides (i.e. to the left and the right of the center of each of the corresponding emitters). In this case, the width of the sub-contacts w_{sub} toward both edges of the corresponding emitters preferably increases symmetrically and monotonically. It is likewise preferred for the spacing a_{sub} between the sub-contacts toward both edges of the corresponding emitters preferably decreases symmetrically and monotonically.

In this case, the variation in the width w_{sub} and/or the spacing a_{sub} of the sub-contacts should preferably be at least 10% from the center toward the edges of the corresponding emitters. Inhomogeneous sub-contacts of this kind having a symmetrical arrangement relative to the center of the corresponding emitters can preferably be used in the central emitters of the laser bar, which generally make up at least 30% of the entirety of the emitters in the laser bar.

Since the edge emitters (emitters 1 and 8) shown in FIG. 1 have a highly asymmetrical temperature profile (greater variation at the outer edges) compared with the central emitters, however, the sub-contacts should preferably likewise be arranged asymmetrically on their two sides. Since the drop in temperature on one side is much greater than on the other, the variation in the width w_{sub} and/or the spacing a_{sub} of the sub-contacts should preferably also be greater on this side starting from the center of the emitter.

For an edge emitter, the variation in the width w_{sub} and/or the spacing a_{sub} of the sub-contacts from the center to the outer edge of the emitter, where the drop in temperature is greater, should preferably be at least 20%, while the variation in the width w_{sub} and/or the spacing a_{sub} of the sub-contacts on the other side of the emitter, where the drop in temperature is less, should preferably be smaller. Inhomogeneous sub-contacts of this kind having an asymmetrical arrangement relative to the center of the corresponding emitters should preferably be used in the emitters in the vicinity of the edges of the laser bar, which generally make up at least up to approximately 35% of the entirety of the emitters on each side of the laser bar.

Further preferred embodiments of the invention follow from the features set out in the dependent claims.

The different embodiments of the invention set out in this application are advantageously able to be combined with one another unless otherwise specified.

### BRIEF DESCRIPTION OF THE DRAWINGS

The invention is described below in exemplary embodiments on the basis of the associated drawings, in which:

FIG. 1 shows simulated lateral temperature distributions in a conventional kW-class 1 cm diode laser bar having 8 emitters (width W=1100 μm) at different power losses on a heat sink having a thermal resistance Rₜₕ=0.05 K/W;

FIG. 2 shows (a) simulated lateral temperature distributions along a single emitter (width W=1100 μm) in a kW-class 1 cm diode laser bar having a thermal resistance Rₜₕ=0.05 K/W at 0.6 kW and 1.0 kW operating power and an emitter spacing of d=255 μm (7 emitters, greater thermal lensing) and d=65 μm (8 emitters, weaker thermal lensing) and (b) the measured lateral far-field divergence angle of individual emitters in a kW-class 1 cm diode laser bar having a thermal resistance Rₜₕ=0.05 K/W and its dependence on the operating power up to 1 KW (d=255 μm having a wider lateral far field and d=65 μm having a narrower lateral far field);

FIG. 3 is a schematic view for forming sub-structures having a conventional homogeneous sub-structure distribution and an inhomogeneous sub-structure distribution according to the invention;

FIG. 4 shows simulated temperature distributions within an emitter (width w=1100 μm) in a kW-class 1 cm diode laser bar (8 emitters) at 1 kW operating power on a heat sink having a thermal resistance Rₜₕ=0.05 K/W that is suitable for a central emitter having (a) a conventional homogeneous sub-structure distribution and (b) a symmetrical inhomogeneous sub-structure distribution according to the invention and is suitable for an edge emitter having (c) a conventional homogeneous sub-structure distribution and (d) an asymmetrical inhomogeneous sub-structure distribution according to the invention;

FIG. 5 shows views of measured (a) power outputs, voltages and conversion efficiencies depending on the operating current and (b) far-field divergence angles at different operating powers for a kW-class 1 cm laser bar having a conventional homogeneous sub-structure distribution and two different variants of a kW-class 1 cm diode laser bar having an inhomogeneous sub-structure distribution according to the invention at a low heat load (thermal resistance Rₜₕ=0.02 K/W) and (c), (d) show the corresponding measurements at a high heat load (thermal resistance Rₜₕ=0.05 K/W).

### DETAILED DESCRIPTION OF THE DRAWINGS

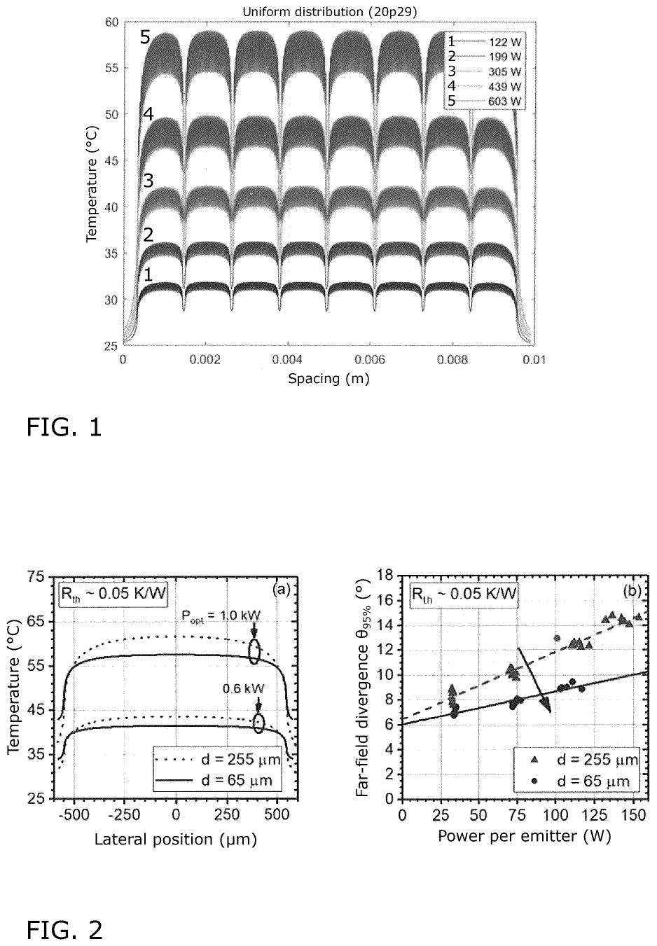

FIG. 1 shows simulated lateral temperature distributions in a conventional kW-class 1 cm diode laser bar having 8 emitters (width W=1100 μm) at different power losses, which is mounted on a heat sink having a thermal resistance of Rₜₕ=0.05 K/W. In particular, this is a GaAs-based semiconductor laser. The thermal resistance relates to the change in the central temperature of the active zone based on the total pumped surface area of the laser bar having increasing power loss (heat). In order to avoid stimulating undesired lateral modes, the individual emitters of the laser bar have homogeneously sub-structured contact layers, wherein the structured regions comprising individual sub-contacts each have a width of 20 μm and a spacing of 9 μm (corresponding to a period p_{sub} of 29 μm) in the simulation shown merely by way of example. The central 6 emitters (emitters 2 to 7) of the laser bar exhibit symmetrical and largely identical temperature distributions, while, at the outer edge emitters (emitters 1 and 8) of the laser bar, asymmetrical temperature distributions are exhibited having a significantly reduced temperature toward the edges of the emitter. At an operating power of 1 KW (corresponding to a power loss of approximately 603 W), the temperature deviation ΔT between the center of the central emitters and their edges is 4.4 K. For the edge emitters, the deviation increases even to above 10 K. The resulting thermal lensing that is generated within the individual emitters gives rise to more higher-order modes and therefore worsens the beam quality of the emitters.

FIG. 2 shows (a) simulated lateral temperature distributions along a single emitter (width W=1100 μm) in a kW-class 1 cm diode laser bar having a thermal resistance Rₜₕ=0.05 K/W at 0.6 KW and 1.0 kW operating power and an emitter spacing of d=255 μm (7 emitters, greater thermal lensing) and d=65 μm (8 emitters, weaker thermal lensing) and (b) the measured lateral far-field divergence angle of individual emitters in a kW-class 1 cm diode laser bar having a thermal resistance Rₜₕ=0.05 K/W and its dependence on the operating power up to 1 KW (d=255 μm having a wider lateral far field and d=65 μm having a narrower lateral far field). In this figure, the direct effect of reduced thermal distortion (lensing) within the individual emitters of the laser bar on the far-field divergence can be identified. In the laser bar having the smaller emitter spacing, the emitters have greater thermal interaction with one another, which prevents a significant drop in temperature in the unpumped region between the pumped regions and thus likewise should bring about a flatter temperature distribution in comparison with the emitters in the laser bar having the greater emitter spacing. This is confirmed by the simulation shown (FIG. 2(a)). The reduced thermal lensing within the emitter reduces the number and the divergence angle of the lateral modes and reduces the total beam divergence angle significantly (FIG. 2(b)), although the edge emitters (marked with a circle in the figure) still have a comparable beam divergence to the emitters in the laser bar having the greater emitter spacing.

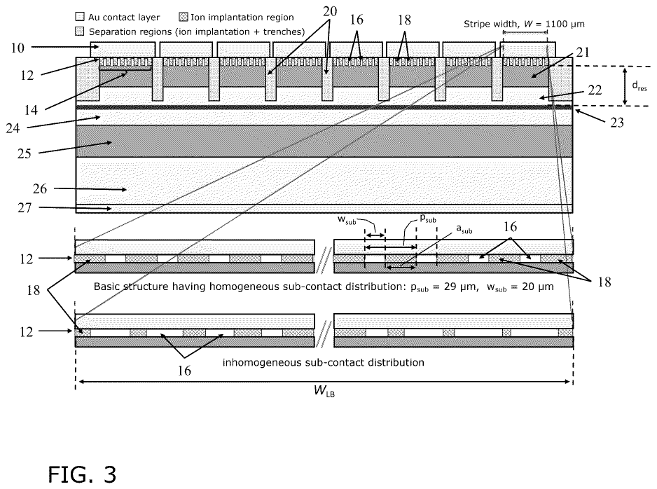

FIG. 3 is a schematic view for forming a structured region 14 having a conventional homogeneous sub-structure distribution and an inhomogeneous sub-structure distribution according to the invention. Here, the contact regions are each formed by a metal contact layer 10 for making planar surface contact with a semiconductor contact layer 12, positioned therebelow, of an epitaxial layer. A structured region 14 having individual sub-contacts 16 is formed under the metal contact layer 10 in the semiconductor contact layer 12 for spatially splitting an operating current which can be supplied over the metal contact layer 10. The individual sub-contacts 16 of a broad-area laser emitter form a sub-structure distribution in this case. The structured regions 14 shown are, by way of example, shown as part of a laser bar having a plurality of broad-area laser emitters arranged beside one another. In the contact region shown having a homogeneous sub-structure distribution according to the prior art, the width w_{sub} and the spacing a_{sub} of the individual sub-contacts 16 of the structured region 14 are each constant in a lateral direction (slow axis) in the semiconductor contact layer 12 under the metal contact layer 10. In the contact region shown according to the invention having an inhomogeneous sub-structure distribution, however, the width w_{sub} and/or the spacing a_{sub} of the individual sub-contacts 16 of the structured region 14 varies in a lateral direction (slow axis) in the semiconductor contact layer 12 under the metal contact layer 10. An inhomogeneous sub-structure distribution according to the invention can preferably be carried out by structuring the resistance of the semiconductor contact layer 12 by means of implantation or doping of foreign atoms, or by implementation of p-n junctions or layers having a wide bandgap. Preferably, the unpumped regions 18 between the individual sub-contacts 16 can therefore be ion implantation regions.

The individual broad-area laser emitters of the laser bar shown are each separated from one another by separation regions 20. They can be formed by accordingly structuring the epitaxial layers, for example by means of deep implantation or appropriate doping with foreign atoms, to increase the electrical resistance in these regions and by etched trenches for optical isolation between the individual emitters. Here, the separation regions 20 can extend over the semiconductor contact layer 12 into underlying epitaxial layers.

This figure also shows, by way of example, an epitaxial layer system as is typically used to construct broad-area laser emitters or corresponding laser bars. This comprises a sequence grown on an n-doped substrate 26, comprising an n-doped cladding layer 25, an n-doped waveguide layer 24, a p-doped waveguide layer 22, and a p-doped cladding layer 21. An active layer 23 is formed between the n-doped waveguide layer 24 and the p-doped waveguide layer 22. The semiconductor contact layer 12 is arranged above the p-doped cladding layer 21 and separates it from the metal (p-side) contact layer 10. The n-doped substrate 26 can be electrically contacted via an additional n-contact layer 27 (metal contact).

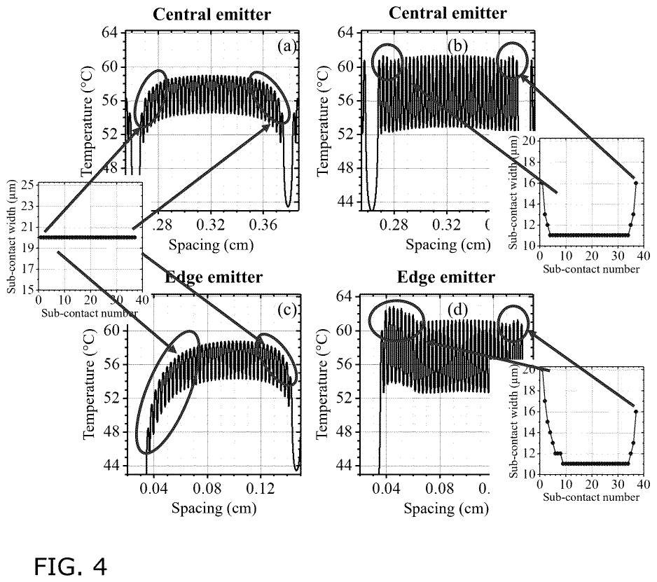

FIG. 4 shows simulated temperature distributions within an emitter (width w=1100 μm) in a kW-class 1 cm diode laser bar (8 emitters) at 1 kW operating power on a heat sink having a thermal resistance Rₜₕ=0.05 K/W that is suitable for a central emitter having (a) a conventional homogeneous sub-structure distribution and (b) a symmetrical inhomogeneous sub-structure distribution according to the invention and is suitable for an edge emitter having (c) a conventional homogeneous sub-structure distribution and (d) an asymmetrical inhomogeneous sub-structure distribution according to the invention. In this case, the widths w_{sub} of the individual sub-contacts are shown in the corresponding insets. The temperature deviation ΔT in the structure according to the invention drops to 0.6 K and is therefore 7 times lower than in the basic structure having a conventional homogeneous sub-structure distribution. Owing to the more strongly asymmetrical temperature distribution in the edge emitters, an asymmetrical sub-structuring having yet wider sub-contacts than in the central emitter structures is preferably used in these edge emitters (cf. FIG. 4(a), 4(c) and 4(b), 4(d)). This reduces the disadvantageous temperature deviation ΔT in the edge emitters to ±1.6 K, which amounts to an improvement by more than 5 times compared with the basic structure.

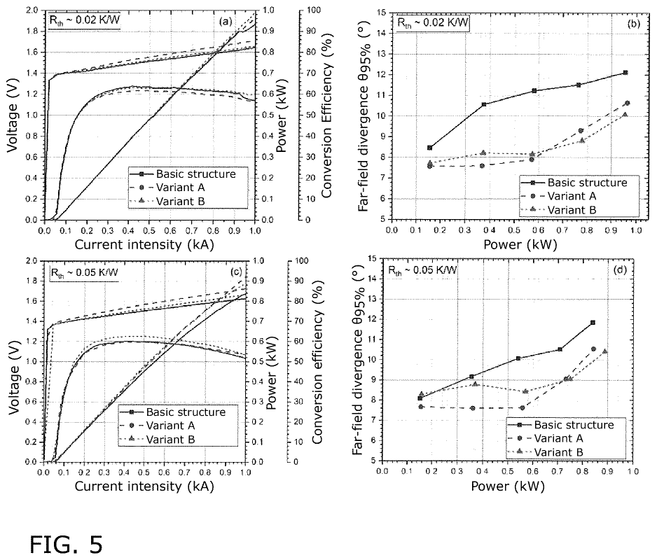

FIG. 5 shows views of measured (a) power outputs, voltages and conversion efficiencies depending on the operating current and (b) far-field divergence angles at different operating powers for a kW-class 1 cm laser bar having a conventional homogeneous sub-structure distribution and two different variants of a kW-class 1 cm diode laser bar having an inhomogeneous sub-structure distribution according to the invention at a low heat load (thermal resistance Rₜₕ=0.02 K/W) and (c), (d) show the corresponding measurements at a high heat load (thermal resistance Rₜₕ=0.05 K/W). For these tests, two different variants of laser bar having a plurality of emitters which have an inhomogeneous sub-structure distribution according to the invention (i.e. a contact region according to the invention) were produced and then operated at different heat loads, which were reached in practice by varying the operating time. The sub-structure distributions of variant A correspond to the embodiment described in FIG. 4(b) and 4(d). In variant B, the widths of the sub-structures w_{sub} are increased by 5 μm without a variation in the period p_{sub}. For comparison, a basic structure having homogeneous sub-structure distribution was also tested according to the embodiment described in FIG. 4(a) and 4(c).

The advantages resulting according to the invention from the inhomogeneous sub-structure distribution can be observed here over the entire tested operating range. Although variant A has a somewhat lower degree of efficiency at a low heat load (e.g. ≈2% drop in the degree of efficiency at 0.8 KW), variant B, having an increased fill factor F, provides a similar degree of efficiency to the basic structure. Furthermore, both variants produce a narrower divergence angle than the basic structure. At a high heat load, both variants provide a higher power output and a lower beam divergence than the basic structure over the entire operating range. In particular, a greater advantage results at the higher operating power, which leads to a beam divergence that is up to 2° lower. Here, the greatest degree of efficiency is achieved by the sub-structure distributions in variant B owing to the particularly flat temperature profile and the greater fill factor F (lower electrical resistance).

### LIST OF REFERENCE SIGNS

10 Metal contact layer (e.g. Au contact layer)
12 Semiconductor contact layer (e.g. p-doped semiconductor contact layer)
14 Structured region (the semiconductor contact layer, e.g. formed by flat implantation of ions)
16 Sub-contacts (formed by the structure of the structured region)
18 Unpumped region (between the individual sub-contacts)
20 Separation regions (between adjacent broad-area laser emitters of a laser bar, e.g. formed by deep implantation or etched trenches)
21 p-doped cladding layer
22 p-doped waveguide layer
23 Active layer
24 n-doped waveguide layer
25 n-doped cladding layer
26 n-doped substrate
27 n-contact layer (metal contact)

1. A contact region of a single broad-area laser emitter, comprising:
a semiconductor contact layer of an epitaxial layer of the broad area laser emitter, and
a metal contact layer for making planar surface contact with the semiconductor contact layer, wherein a structured region comprising individual sub-contacts is formed under the metal contact layer in the semiconductor contact layer for spatially splitting an operating current which can be supplied over the metal contact layer,
wherein a width w_{sub} and/or a spacing a_{sub} of the individual sub-contacts varies in a lateral direction of the broad-area laser emitter.

2. The contact region according to claim 1, wherein the contact region extends over a lateral stripe width W≥150 μm.

3. The contact region according to claim 1, wherein the width of a sub-contact is w_{sub}≤200 μm.

4. The contact region according to claim 1, wherein the spacing between adjacent sub-contacts is a_{sub}≤50 μm.

5. The contact region according to claim 1, wherein a period of the sub-contacts p_{sub} varies by less than 10% or a period of the sub-contacts p_{sub} is constant.

6. The contact region according to claim 1, wherein a fill factor F of the structured contact layer is between 30% and 95%.

7. The contact region according to claim 1, wherein the width of the sub-contacts w_{sub} increases toward the edges and/or the spacing of the sub-contacts a_{sub} decreases toward the edges.

8. The contact region according to claim 1, wherein the width w_{sub} and/or spacing a_{sub} of the sub-contacts additionally varies in a longitudinal direction from a front face of the broad-area laser emitter to a rear face of the broad-area laser emitter.

9. The contact region according to claim 8, wherein the width of the sub-contacts w_{sub} increases in the longitudinal direction and/or the spacing of the sub-contacts a_{sub} decreases in the longitudinal direction.

10. The contact region according to claim 1, wherein the contact region is produced by structuring the resistance of the semiconductor contact layer by means of implantation or doping of foreign atoms, or by implementation of p-n junctions or layers having a wide bandgap.

11. A broad-area laser emitter having a contact region according claim 1.

12. A laser bar comprising a plurality of broad-area laser emitters arranged beside one another, wherein at least one broad-area laser emitter comprises a contact region according to claim 1.

13. The laser bar according to claim 12, wherein at least one broad-area laser emitter having a contact region according to claim 1 is arranged in the central region of the laser bar and the individual sub-contacts of the broad-area laser emitter are designed to be symmetrical relative to the center of the structured region in the lateral direction.

14. The laser bar according to claim 12, wherein at least one broad-area laser emitter having a contact region according to claim 1 is arranged in the edge region of the laser bar and the individual sub-contacts of the broad-area laser emitter are formed to be asymmetrical relative to the center of the structured region in the lateral direction.

15. The laser bar according to claim 14, wherein the variation in the width w_{sub} and/or the spacing a_{sub} of the sub-contacts from the center of the structured region toward the central region of the laser bar is less than toward the edges of the laser bar.

16. The contact region according to claim 1, wherein the spacing between adjacent sub-contacts a_{sub} is greater than 1 μm.

17. The contact region according to claim 1, wherein the variation in the width w_{sub} and/or the spacing a_{sub} of the center of the structured region toward its edges is at least 10%.

18. The contact region according to claim 8, wherein the variation in the width w_{sub} and/or the spacing a_{sub} from the front face of the broad-area laser emitter to the rear face of the broad-area laser emitter is at least 10%.

19. The laser bar according to claim 15, wherein the difference in the variation is at least 10%.
